(19) United States
(12) Patent Application Publication
(10) Pub. No.: US 2025/0300047 A1
(43) Pub. Date: Sep. 25, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Min-Han CHUANG, Taichung City (TW); Ho-Chuan LIN, Taichung City (TW); Chia-Chu LAI, Taichung City (TW)

(73) Assignee: SILICONWARE PRECISION INDUSTRIES CO., LTD., Taichung City (TW)

(21) Appl. No.: 18/813,342

(22) Filed: Aug. 23, 2024

(30) Foreign Application Priority Data
Mar. 20, 2024 (TW) 113110372

(51) Int. Cl. H01L 23/498; H01L 23/31

(52) U.S. Cl. CPC H01L 23/49816; H01L 23/3114

(57) ABSTRACT

Provided are an electronic package and a manufacturing method thereof. An electronic component is embedded in an encapsulation layer, the electronic component has a first electrode pad and a second electrode pad on two opposite sides thereof to form a double-sided power supply structure, and thus a circuit structure and a wiring structure on the two opposite sides of the electronic component can be electrically connected to the first electrode pad and the second electrode pad, thereby it is beneficial for reducing loss of the power.

### BACKGROUND

### 1. Technical Field

The present disclosure relates to a semiconductor device, and more particularly, to an electronic package for improving performance of products and a manufacturing method thereof.

### 2. Description of Related Art

In recent years, with the continuous maturity and development of semiconductor process technology, various high-efficiency electronic products have been innovated, and the functions of electronic products have developed towards humanization and multi-function. However, internal of electronic products have integrated circuit (IC) elements with various functions. IC packaging plays a very important role in the manufacturing process of electronic components, and the IC packaging can be roughly divided into pin in hole (PIH) type and surface mount technology (SMT) type. The PIH type may be such as dual in-line package (DIP) and pin grid array (PGA), the SMT type may be for example, the types of wire bonding package (WB), tape automatic bonding (TAB), flip chip (FC) and ball grid array package (BGA), fan-out type package structure, and so on, and each package type has its particularity and application fields.

However, no matter what packaging type is used in the conventional semiconductor packaging process, providing improvements in the performance of end products has encountered an obstacle. For example, the problem of excessive power loss is constantly difficult to solve.

Therefore, there is a need for addressing the aforementioned shortcomings in the prior art.

### SUMMARY

In view of the aforementioned shortcomings of the prior art, the present disclosure provides an electronic package which comprises: an encapsulation layer; an electronic component embedded in the encapsulation layer, wherein the electronic component has a first side and a second side opposite to the first side, the first side has a plurality of first electrode pads, and the second side has a plurality of second electrode pads; a circuit structure disposed on the first side of the electronic component and electrically connected to the plurality of first electrode pads; and a wiring structure disposed on the second side of the electronic component and electrically connected to the plurality of second electrode pads, wherein the wiring structure has a plurality of electrical functional pads and a plurality of conductive blind holes, and therefore a single one of the electrical functional pads is electrically connected to a single one of the second electrode pads via the plurality of conductive blind holes.

The present disclosure also provides a method of manufacturing an electronic package, and the method comprises: covering an electronic component with an encapsulation layer, wherein the electronic component has a first side and a second side opposite to the first side, and the first side has a plurality of first electrode pads, and the second side has a plurality of second electrode pads; forming a circuit structure on the first side of the electronic component, in a manner that the circuit structure is electrically connected to the plurality of first electrode pads; and forming a wiring structure on the second side of the electronic component, in a manner that the wiring structure is electrically connected to the plurality of second electrode pads, wherein the wiring structure has a plurality of electrical functional pads and a plurality of conductive blind holes, and a single one of the electrical functional pads is electrically connected to a single one of the second electrode pads via a plurality of conductive blind holes.

In the aforementioned electronic package and method, a function of the first electrode pad is different from a function of the second electrode pad.

In the aforementioned electronic package and method, the first electrode pad is a signal pad, and the second electrode pad is a power pad. Alternatively, the second electrode pad is a signal pad, and the first electrode pad is a power pad. Further, the power pad is different in width from the signal pad. For example, a width of the power pad is greater than a width of the signal pad.

In the aforementioned electronic package and method, further comprising embedding a plurality of conductive pillars in the encapsulation layer, and electrically connecting the plurality of conductive pillars to the circuit structure and the wiring structure.

In the aforementioned electronic package and method, further comprising disposing an electronic device on the circuit structure, and electrically connecting the electronic device to the circuit structure.

In the aforementioned electronic package and method, further comprising forming a cover layer on the circuit structure.

In the aforementioned electronic package and method, further comprising disposing an electronic device on the wiring structure, and electrically connecting the electronic device to the wiring structure.

As can be understood from the above, in the electronic package and manufacturing method of the present disclosure, the first electrode pad and the second electrode pad are mainly provided on opposite sides of the electronic component to form a double-sided power supply structure, and the electrical functional pad can be electrically connected to the second electrode pad by the plurality of the conductive blind holes. Therefore, compared with the prior art, the electronic package of the present disclosure can reduce losses of the power supply when the electrical functional pad and the second electrode pad are both power pads.

### BRIEF DESCRIPTION OF THE DRAWINGS

FIG. 1A to FIG. 1F are schematic cross-sectional views of the manufacturing method of the electronic package according to the first embodiment of the present disclosure.

FIG. 1E-1 is a partially enlarged schematic diagram of FIG. 1E.

FIG. 2A and FIG. 2B are schematic cross-sectional views of other aspects of FIG. 1F.

FIG. 3 is a schematic cross-sectional view of the manufacturing method of the electronic package according to the second embodiment of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

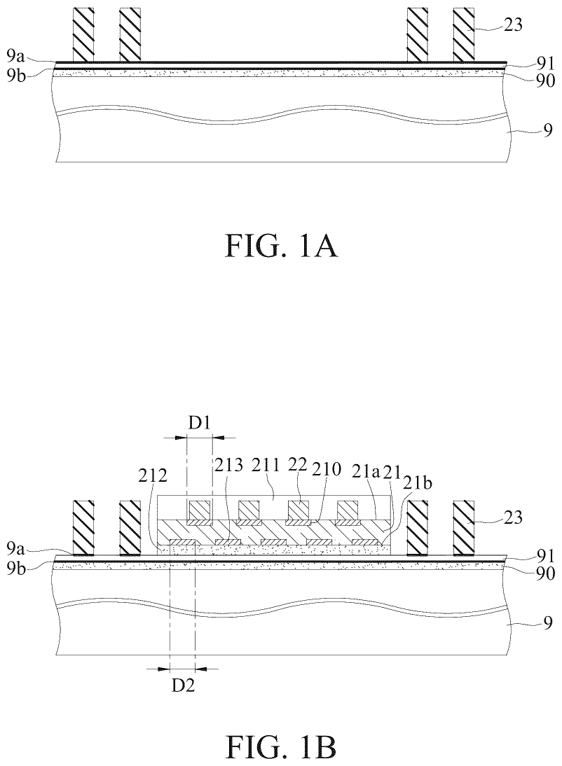

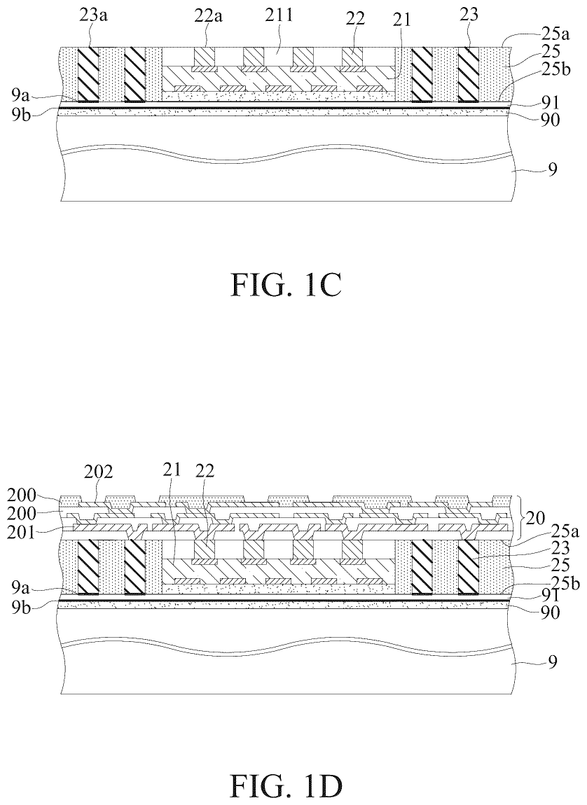

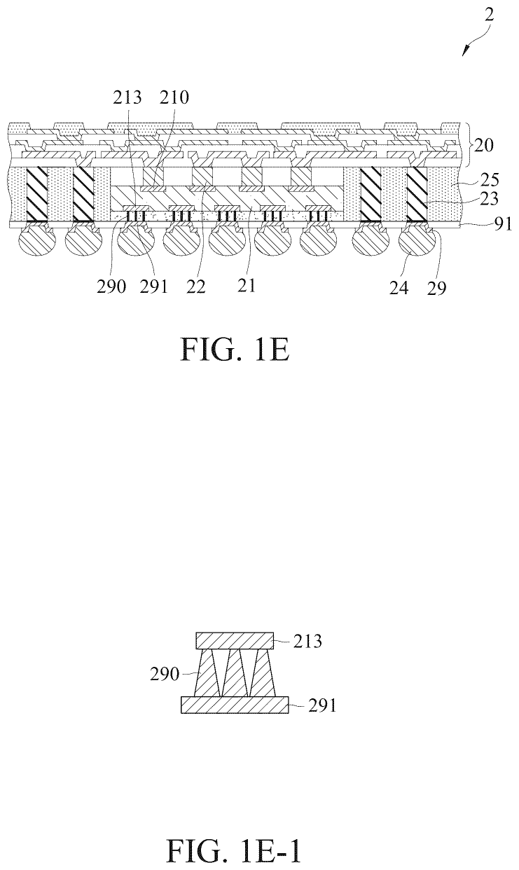

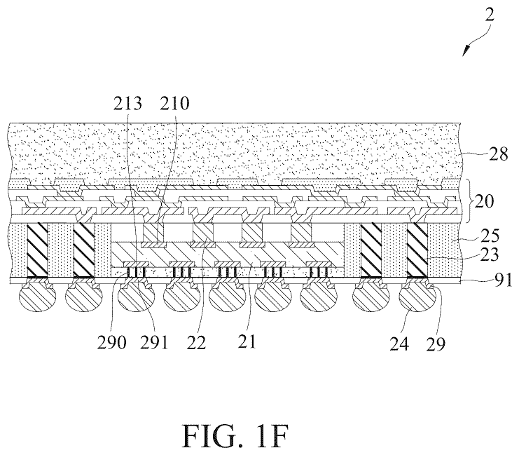

FIG. 1A to FIG. 1F are schematic cross-sectional views of the manufacturing method of the electronic package 2 according to the first embodiment of the present disclosure.

As shown in FIG. 1A and FIG. 1B, a carrier board 9 having a seed layer 9a is provided, and a plurality of conductive pillars 23 are formed on the carrier board 9 by the seed layer 9a. Next, at least one electronic component 21 is disposed on the carrier board 9, and a plurality of conductors 22 are bonded to and electrically connected to the electronic component 21. The conductors 22 are for example but not limited to, a conductive circuit, solder balls in a spherical shape, metal materials in a columnar shape such as a copper pillar or a solder bump, or a stud-shaped conductive member made by a wire bonding machine.

The carrier board 9 is, for example, a board body made of semiconductor materials (such as silicon or glass), on which a release layer 90, a metal layer 9b such as titanium/copper and an insulating layer 91 such as a dielectric material or a solder mask material are sequentially formed by, for example, coating, such that the seed layer 9a is disposed on the insulating layer 91.

In this embodiment, a patterned resist layer (not shown) can be formed on the seed layer 9a, and thus a partial surface of the seed layer 9a is exposed by the resist layer for arranging the conductive pillars 23. After producing the conductive pillars 23, the patterned resist layer and the seed layer 9a underneath are removed, as shown in FIG. 1B.

Furthermore, the conductive pillars 23 are made of a metal material such as copper or a solder material, and the seed layer 9a is made of a material such as titanium/copper.

The electronic component 21 is a semiconductor wafer having a first side 21a and a second side 21b opposite to the first side 21a. The first side 21a has a plurality of first electrode pads 210, and the second side 21b has a plurality of second electrode pads 213.

In this embodiment, the electronic component 21 belongs to the technical field of backside power delivery chips, and differs from conventional chips in that the I/O signal, power and ground circuits of the element in the conventional chips would transmit outward in the same direction through dielectric materials and copper wires, and then connect to external circuits such as Cu pillars, solder balls, and substrates. To increase the transmission speed and reduce loss of electrical power, the backside of the backside power delivery chips can be thinned, and the power and ground contacts can be derived from the backside. Therefore, the first electrode pad 210 and the second electrode pad 213 are not electrically conducted by a through-silicon via (TSV), that is, the electronic component 21 is not in a form of a through silicon interposer (TSI).

Furthermore, the second side 21b of the electronic component 21 is adhered to the insulating layer 91 by a bonding layer 212, and the first side 21a has a protective film 211 such as a passivation material, and therefore the conductor 22 is formed in the protective film 211.

Also, the functions between the first electrode pad 210 and the second electrode pad 213 are different. For example, the first electrode pad 210 is a signal pad, and the second electrode pad 213 is a power pad. Alternatively, the second electrode pad 213 is a signal pad, and the first electrode pad 210 is a power pad. Further, a width D2 of the power pad is different from a width D1 of the signal pad. For example, a width D2 of the power pad (e.g., the second electrode pad 213) is greater than a width D1 of the signal pad (e.g., the first electrode pad 210).

As shown in FIG. 1C, an encapsulation layer 25 is formed on the insulating layer 91 of the carrier board 9, and thus the encapsulation layer 25 covers the electronic component 21, the conductors 22 and the conductive pillars 23. The encapsulation layer 25 has a first surface 25a and a second surface 25b opposite to the first surface 25a, and the protective film 211, an end surface 22a of the conductor 22 and an end surface 23a of the conductive pillars 23 are exposed from the first surface 25a of the encapsulation layer 25, and the second surface 25b of the encapsulation layer 25 is bonded to the insulating layer 91 of the carrier board 9.

In this embodiment, the encapsulation layer 25 is an insulating material, such as polyimide (PI), dry film, encapsulants of epoxy resin or molding compound. For example, the encapsulation layer 25 may be formed on the insulating layer 91 by selecting liquid compound, injection, lamination or compression molding in the process.

Furthermore, a leveling process can be used to make the first surface 25a of the encapsulation layer 25 flush with the protective film 211, the end surface 23a of the conductive pillars 23 and the end surface 22a of the conductive body 22. Therefore, the end surface 23a of the conductive pillars 23 and the end surface 22a of the conductor 22 are exposed from the first surface 25a of the encapsulation layer 25. For example, partial materials of the protective film 211, partial materials of the conductive pillars 23, partial materials of the conductor 22 and partial materials of the encapsulation layer 25 are removed in the leveling process by grinding.

As shown in FIG. 1D, a circuit structure 20 is formed on the first surface 25a of the encapsulation layer 25, and the circuit structure 20 is electrically connected to the conductive pillars 23 and the conductor 22.

In this embodiment, the circuit structure 20 includes a plurality of insulating layers 200 and a plurality of circuit layers 201 disposed on the insulating layer 200, such as a redistribution layer (RDL) specification, and thus the circuit layers 201 are electrically connected to the conductive pillars 23 and the conductor 22. The outermost insulating layer 200 can be used as a solder mask layer, thereby the outermost circuit layer 201 is exposed from the solder mask layer to serve as an electrical contact pad 202, such as micro pad (as known as μ-pad). Alternatively, the circuit structure 20 may only include a single insulating layer 200 and a single circuit layer 201.

Furthermore, a material forming the circuit layer 201 can be copper, and a material forming the insulating layer 200 can be a dielectric material such as polybenzoxazole (PBO), polyimide (PI), prepreg (PP), or a solder mask material such as green paint, ink, etc.

As shown in FIG. 1E, the carrier board 9 as well as the release layer 90 and the metal layer 9b thereon are removed, and the insulating layer 91 is retained. Next, a wiring structure 29 electrically connected to the conductive pillars 23 is formed on the insulating layer 91, and the wiring structure 29 has a plurality of conductive blind holes 290 electrically connected to the second electrode pad 213. Therefore, a single second electrode pad 213 is connected to the plurality of the conductive blind holes 290 (such as three) to obtain the electronic package 2 of the present disclosure.

In this embodiment, when the release layer 90 is lifted off, the metal layer 9b is used as a barrier to avoid the insulating layer 91 being damaging. After the carrier board 9 and the release layer 90 thereon are removed, the metal layer 9b is removed by etching.

Furthermore, the insulating layer 91 is formed with a plurality of openings by laser, and thus the end surfaces 23a of the conductive pillars 23 along with parts of the second surfaces 25b of the encapsulation layer 25 are exposed from the openings for bonding with the wiring structure 29. For example, the wiring structure 29 can be formed on the insulating layer 91 by an RDL process and have a plurality of electrical functional pads 291 to bond with conductive components 24 such as solder bumps, copper bumps or others.

Therefore, by providing the carrier board 9 with the insulating layer 91, the wiring structure 29 can be formed by utilizing the insulating layer 91 after the carrier board 9 is removed, thereby there is no need to arrange a dielectric layer. Hence, time and steps of the process can be reduced, and the purpose of cutting costs of the process can be achieved.

Also, a single electrical functional pad 291 is connected to the plurality of the conductive blind holes 290 (such as three), as shown in FIG. 1E-1. For example, the electrical functional pad 291 and the second electrode pad 213 are both power pads.

In addition, in other embodiments, as shown in FIG. 1F, a cover layer 28 can be formed on the circuit structure 20. The cover layer 28 is an insulating material, such as polyimide (PI), dry film, encapsulants of epoxy resin or molding compound, which can be formed on the circuit structure 20 by lamination or molding. It should be understood that the materials for forming the cover layer 28 may be the same as or different from the material of the encapsulation layer 25.

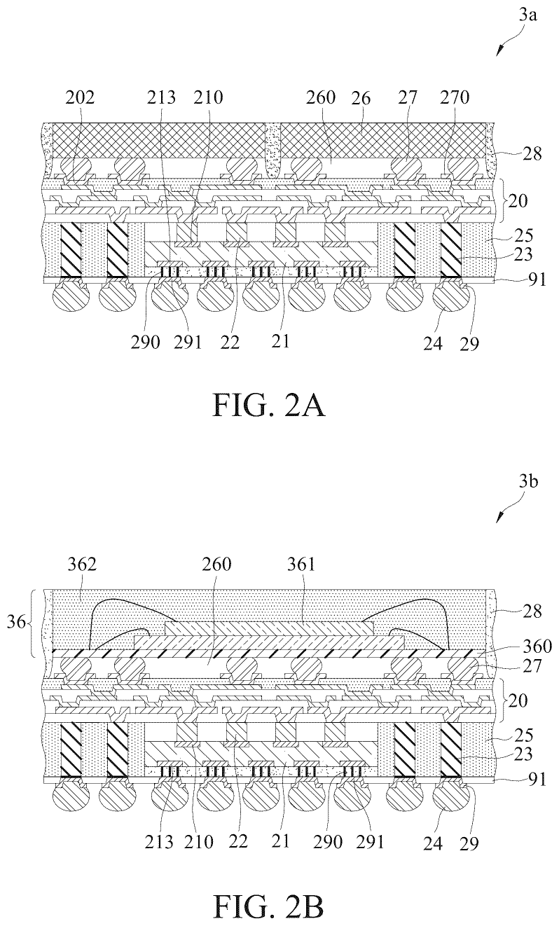

Alternatively, as shown in the electronic package 3a in FIG. 2A, at least one electronic device 26 can be disposed on the circuit structure 20, and then the electronic device 26 is covered with the cover layer 28.

The electronic device 26 is electrically connected to the electrical contact pad 202 by a plurality of conductive bumps 27 such as solder bumps, copper bumps or others.

In this embodiment, a plurality of electronic devices 26 are arranged in a specification of chips such as graphics processing unit (GPU), high bandwidth memory (HBM) and so on, but is not limited thereto.

Furthermore, an under bump metallurgy (UBM) 270 can be formed on the electrical contact pad 202 to facilitate the bonding of the conductive bump 27.

Also, partial materials of the cover layer 28 can be removed through a leveling process, such as grinding, such that the upper surface of the cover layer 28 is flush with the surface of the electronic device 26, thereby the electronic device 26 is exposed from the cover layer 28.

In addition, the cover layer 28 can cover the electronic device 26 and the conductive bumps 27 at the same time. Alternatively, the underfill 260 may be formed between the electronic device 26 and the circuit structure 20 to cover the conductive bumps 27, and then the cover layer 28 may be formed to cover the underfill 260 and the electronic device 26.

Alternatively, as shown in the electronic package 3b in FIG. 2B, the electronic device 36 may be a package module including an encapsulation layer 360, at least one semiconductor chip 361 disposed on and electrically connected to the encapsulation layer 360, and an encapsulant 362 covering the semiconductor chip 361.

Therefore, in the manufacturing method of this embodiment, the first electrode pad 210 and the second electrode pad 213 are mainly provided on opposite sides of the electronic component 21 to form a double-sided power supply structure, so that the electrical functional pad 291 can be electrically connected to the second electrode pad 213 by the plurality of conductive blind holes 290. Therefore, compared with the prior art, the electronic package 2, 3a, 3b of the present disclosure can reduce loss of the power when the electrical functional pad 291 and the second electrode pad 213 are both power pads.

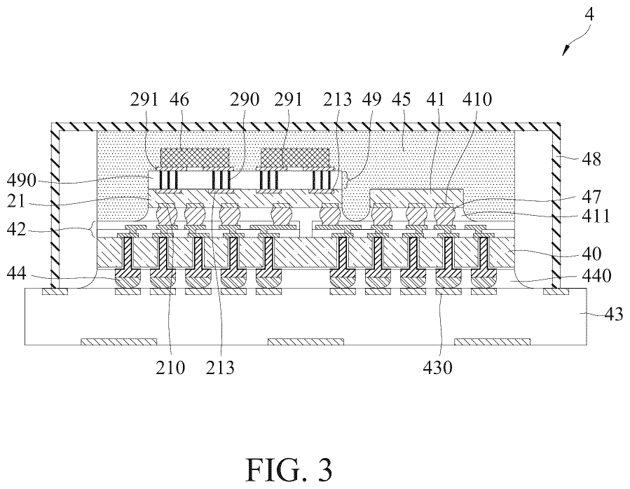

FIG. 3 is a schematic cross-sectional view of the manufacturing method of the electronic package 4 according to the second embodiment of the present disclosure. The difference between this embodiment and the first embodiment lies in the packaging method, and the descriptions of similarities are omitted below.

As shown in FIG. 3, electronic components 21, 41 are stacked on a circuit structure 40.

The circuit structure 40 has a silicon-containing board body, such as a function chip, a through silicon interposer (TSI) or a glass substrate, and the board body is arranged with conductive wires.

In this embodiment, the circuit structure 40 is a TSI, which has TSVs and a circuit part 42. For example, the circuit part 42 includes at least one dielectric layer and an RDL combined with the dielectric layer, and the RDL is electrically connected to the TSV.

It should be understood that the form of the circuit structure 40 can be designed according to requirements and is not limited to as such.

On the other hand, a plurality of conductive components 44, such as metal pillars (i.e., copper pillars) and/or solder materials, can be formed on a lower side of the circuit structure 40, and thus the plurality of conductive components 44 can be bonded to end surfaces of the plurality of TSVs for connecting to a substrate structure 43.

The substrate structure 43 is, for example, an encapsulation substrate with a core layer or a coreless encapsulation substrate, which is configured with at least one wiring layer 430. Therefore, the plurality of conductive components 44 are electrically connected to the wiring layer 430.

In this embodiment, an underfill 440 can be formed on the substrate structure 43 so as to cover the plurality of conductive components 44.

The electronic components 21, 41 are disposed on the circuit structure 40 and are electrically connected to the circuit part 42.

In this embodiment, the electronic components 21, 41 are semiconductor chips, and the first side thereof is disposed with a plurality of first electrode pads 210, 410. The electronic components 21, 41 are disposed on the circuit structure 40 and are electrically connected to the circuit part 42 in a flip-chip manner through a plurality of conductive bumps 47 such as solder materials, and then the conductive bumps 47 are covered with the underfill 411.

Furthermore, one of the electronic components 21 is disposed with a plurality of second electrode pads 213 on the second side thereof, and a wiring structure 49 is formed on the second side. The wiring structure 49 includes an insulating layer 490, electrical functional pads 291 formed on the insulating layer 490, and a plurality of conductive blind holes 290 formed in the insulating layer 490 and electrically connected to the second electrode pads 213 and the electrical functional pads 291. As such, a single second electrode pad 213 and a single electrical functional pad 291 are connected to the plurality of the conductive blind holes 290 (such as three).

Further, at least one electronic device 46 can be disposed on the wiring structure 49 such that the electronic device 46 is electrically connected to the electrical functional pad 291. In this embodiment, the electronic device 46 is an inactive element, such as a resistor, a capacitor, and an inductor.

Also, an encapsulation layer 45 is formed on the carrier structure 40 such that the encapsulation layer 45 covers the electronic components 21, 41 for bonding a heat dissipation member 48 on the encapsulation layer 45. For example, the encapsulation layer 45 is a heat dissipation glue, and the heat dissipation member 48 is a frame body, and support legs thereof are disposed on the substrate structure 43, and thus the heat dissipation sheet is attached to the encapsulation layer 45.

Therefore, in the manufacturing method of this embodiment, the first electrode pad 210 and the second electrode pad 213 are mainly provided on opposite sides of one of the electronic components 21 to form a double-sided power supply structure, such that the electrical functional pad 291 can be electrically connected to the second electrode pad 213 by the plurality of conductive blind holes 290. Therefore, compared with the prior art, the electronic package 4 of the present disclosure can reduce the power loss when both the electrical functional pad 291 and the second electrode pad 213 are power pad.

The present disclosure also provides the electronic package 2, 3a, 3b, 4 including the encapsulation layer 25, 45, the electronic component 21, the circuit structure 20, 40 and the wiring structure 29, 49.

The electronic component 21 is embedded in the encapsulation layer 25, 45, and the electronic component 21 has the first side 21a and the second side 21b opposite to the first side 21a, and the first side 21a has the plurality of first electrode pads 210, and the second side 21b has the plurality of second electrode pads 213.

The circuit structure 20, 40 is disposed on the first side 21a of the electronic component 21 and the encapsulation layers 25 and 45 and are electrically connected to the plurality of first electrode pads 210.

The wiring structure 29, 49 is disposed on the second side 21b of the electronic component 21 and electrically connected to the plurality of second electrode pads 213, and the wiring structure 29, 49 has the plurality of electrical functional pads 291 and the plurality of conductive blind holes 290, and therefore, a single electrical functional pad 291 is electrically connected to a single second electrode pad 213 by the plurality of conductive blind holes 290.

In one embodiment, the function of the first electrode pad 210 is different from the function of the second electrode pad 213.

In one embodiment, the first electrode pad 210 is a signal pad, and the second electrode pad 213 is a power pad. Alternatively, the second electrode pad 213 is a signal pad, and the first electrode pad 210 is a power pad. Further, a width D2 of the power pad is different from a width D1 of the signal pad. For example, the width D2 of the power pad is greater than the width D1 of the signal pad.

In one embodiment, the electronic package 2, 3a, 3b further includes at least one conductive pillar 23 embedded in the encapsulation layer 25, and the conductive pillar 23 is electrically connected to the circuit structure 20 and the wiring structure 29.

In one embodiment, the electronic package 3a, 3b further comprises at least one electronic device 26, 36 disposed on the circuit structure 20, and the electronic device 26, 36 is electrically connected to the circuit structure 20.

In one embodiment, the electronic package 2, 3a, 3b further comprises a cover layer 28 formed on the circuit structure 20.

In one embodiment, the electronic package 4 further comprises at least one electronic device 46 disposed on and electrically connected to the wiring structure 49.

In view of the above, in the electronic package and manufacturing method thereof provided in the present disclosure, the first electrode pad and the second electrode pad are mainly provided on opposite sides of the electronic component to form a double-sided power supply structure, thereby the electrical functional pad can be connected to the second electrode pad by the plurality of the conductive blind holes. Therefore, compared with the prior art, the electronic package of the present disclosure can reduce loss of the power when the electrical functional pad and the second electrode pad are both power pads.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulation layer;
an electronic component embedded in the encapsulation layer, wherein the electronic component has a first side and a second side opposite to the first side, the first side has a plurality of first electrode pads, and the second side has a plurality of second electrode pads;
a circuit structure disposed on the first side of the electronic component and electrically connected to the plurality of first electrode pads; and
a wiring structure disposed on the second side of the electronic component and electrically connected to the plurality of second electrode pads, wherein the wiring structure has a plurality of electrical functional pads and a plurality of conductive blind holes, such that a single electrical functional pad is electrically connected to a single second electrode pad by the plurality of conductive blind holes.

2. The electronic package of claim 1, wherein a function of the first electrode pad is different from a function of the second electrode pad.

3. The electronic package of claim 1, wherein the first electrode pad is a signal pad, and the second electrode pad is a power pad.

4. The electronic package of claim 1, wherein the second electrode pad is a signal pad, and the first electrode pad is a power pad.

5. The electronic package of claim 3, wherein a width of the power pad is different from a width of the signal pad.

6. The electronic package of claim 3, wherein a width of the power pad is greater than a width of the signal pad.

7. The electronic package of claim 1, further comprising a plurality of conductive pillars embedded in the encapsulation layer and electrically connected to the circuit structure and the wiring structure.

8. The electronic package of claim 1, further comprising an electronic device disposed on the circuit structure and electrically connected to the circuit structure.

9. The electronic package of claim 1, further comprising a cover layer formed on the circuit structure.

10. The electronic package of claim 1, further comprising an electronic device disposed on and electrically connected the wiring structure.

11. A method of manufacturing an electronic package, comprising:
covering an electronic component by an encapsulation layer, wherein the electronic component has a first side and a second side opposite to the first side, the first side has a plurality of first electrode pads, and the second side has a plurality of second electrode pads;
forming a circuit structure on the first side of the electronic component, and electrically connecting the circuit structure to the plurality of first electrode pads; and
forming a wiring structure on the second side of the electronic component, and electrically connecting the wiring structure to the plurality of second electrode pads, wherein the wiring structure has a plurality of electrical functional pads and a plurality of conductive blind holes, and a single one of the electrical functional pads is electrically connected to a single one of the second electrode pads via the plurality of conductive blind holes.

12. The method of claim 11, wherein the first electrode pad is different in function from the second electrode pad.

13. The method of claim 11, wherein the first electrode pad is a signal pad, and the second electrode pad is a power pad.

14. The method of claim 11, wherein the second electrode pad is a signal pad, and the first electrode pad is a power pad.

15. The method of claim 13, wherein a width of the power pad is different from a width of the signal pad.

16. The method of claim 13, wherein a width of the power pad is greater than a width of the signal pad.

17. The method of claim 11, further comprising embedding a plurality of conductive pillars in the encapsulation layer, thereby the plurality of conductive pillars being electrically connected to the circuit structure and the wiring structure.

18. The method of claim 11, further comprising disposing an electronic device on the circuit structure, and electrically connecting the electronic device to the circuit structure.

19. The method of claim 11, further comprising forming a cover layer on the circuit structure.

20. The method of claim 11, further comprising disposing an electronic device on the wiring structure, and electrically connecting the electronic device to the wiring structure.
